(19) United States
(12) Patent Application Publication
(10) Pub. No.: US 2024/0332888 A1
(43) Pub. Date: Oct. 3, 2024

(54) LASER MODULE

(71) Applicant: TDK CORPORATION, Tokyo (JP)

(72) Inventors: Tomohito Mizuno, Tokyo (JP); Hideaki Fukuzawa, Tokyo (JP); Tsuyoshi Komaki, Tokyo (JP); Tetsuya Shibata, Tokyo (JP); Takeshi Nojiri, Tokyo (JP)

(73) Assignee: TDK CORPORATION, Tokyo (JP)

(21) Appl. No.: 18/616,913

(22) Filed: Mar. 26, 2024

(30) Foreign Application Priority Data
Mar. 30, 2023 (JP) 2023-055997

(51) Int. Cl. H01S 5/02253; G02B 1/00; G02B 3/08; G02B 27/30; H01S 5/40

(52) U.S. Cl. CPC H01S 5/02253; G02B 1/002; G02B 3/08; G02B 27/30; H01S 5/4093

(57) ABSTRACT

A laser module includes: a light source that emits laser light; a housing that accommodates the light source and is provided with an emission port through which the laser light is emitted; a sealing member having optical transparency that seals the emission port and has a first surface and a second surface intersecting an emission direction of the laser light; and a first metasurface lens provided on the first surface.

### CROSS-REFERENCE TO RELATED APPLICATION

This application is based on Japanese Patent Application No. 2023-55997 filed with the Japan Patent Office on Mar. 30, 2023 and claims the benefit of priority thereto. The entire contents of the Japanese patent application are incorporated herein by reference.

### TECHNICAL FIELD

The present disclosure relates to a laser module.

### BACKGROUND

Laser modules that emit laser light are known. For example, Japanese Unexamined Patent Application Publication No. 2022-21419 discloses a laser module including a laser diode, a collimating lens, and an imaging lens.

### SUMMARY

In the laser module described in Japanese Unexamined Patent Application Publication No. 2022-21419, the collimating lens is disposed at a position away from a light source. Therefore, since it is necessary to dispose the lens at a position separated from the emission end of the light source by the focal length of the lens, there is a concern that the laser module may be enlarged.

The present disclosure describes a laser module that can be miniaturized.

A laser module according to one aspect of the present disclosure includes: a light source that emits laser light; a housing that accommodates the light source and is provided with an emission port through which the laser light is emitted; a sealing member having optical transparency that seals the emission port and has a first surface and a second surface intersecting an emission direction of the laser light; and a first metasurface lens provided on the first surface.

In the laser module, the first metasurface lens is provided on the first surface of the sealing member that seals the emission port of the housing. Since the focal distance of the first metasurface lens is adjustable, the distance between the emission end of the light source and the first metasurface lens can be shortened. As a result, the laser module can be miniaturized.

In some embodiments, the first metasurface lens may include a plurality of columnar bodies having optical transparency. In this case, a phase delay of the laser light occurs by the laser light passing through the columnar body. Therefore, a desired lens function can be obtained by appropriately adjusting the phase delay occurring in each columnar body.

In some embodiments, a cross-sectional area intersecting the emission direction of each of the plurality of columnar bodies may be set in accordance with a position of a columnar body. In this case, as the cross-sectional area is larger, the phase delay of the laser light occurring in the columnar body becomes larger. Therefore, a desired lens function can be obtained by appropriately setting the above-described cross-sectional area of the columnar body in accordance with the position of the columnar body.

In some embodiments, the plurality of columnar bodies may be concentrically aligned, and the plurality of columnar bodies may be arranged with a periodic change in the cross-sectional areas of the plurality of columnar bodies in a direction away from a center point of the concentric circle. The lens function can be realized by increasing or decreasing the phase delay occurring in the columnar body as the distance from the center point of the metasurface lens increases. However, the range in which the phase delay occurring in the columnar body can be changed is limited. Since the phase of light has a periodicity of every 2π radians, a lens function can be realized by a periodic change in the cross-sectional areas of the plurality of columnar bodies in a direction away from the center point of the concentric circle.

In some embodiments, the first metasurface lens may function as a collimating lens. In this case, the laser light emitted from the light source can be converted into collimated light.

In some embodiments, the second surface may be an inner surface covering the emission port, and the first surface may be an outer surface opposite to the inner surface. In this case, the first metasurface lens is provided on the outer surface of the sealing member. Therefore, since the first metasurface lens can be kept away from the light source, the beam diameter of the laser light that has reached the first metasurface lens can be increased.

In some embodiments, the above-described laser module may further include a second metasurface lens provided on the second surface. The second metasurface lens may function as a beam expander. In this case, the laser light can be incident on the first metasurface lens after the divergence angle of the laser light is increased. Therefore, since the distance between the emission end of the light source and the first metasurface lens can be further shortened, the laser module can be further miniaturized.

In some embodiments, the laser module may further include a cover layer covering the first metasurface lens. In this case, since the first metasurface is covered with the cover layer, the first metasurface lens is not exposed to the outside air. This makes it possible to reduce the possibility that the first metasurface lens is stained or damaged.

In some embodiments, the first surface may be an inner surface covering the emission port, and the second surface may be an outer surface opposite to the inner surface. In this case, the first metasurface lens is provided on the inner surface of the sealing member. That is, since the first metasurface faces the space in the housing, the first metasurface lens is not exposed to the outside air. This makes it possible to reduce the possibility that the first metasurface lens is stained or damaged.

In some embodiments, the above-described laser module may further include a mask that removes a part of light emitted from the first metasurface lens. In this case, the stray light can be removed without increasing the size of the laser module.

According to each aspect and each embodiment of the present disclosure, a laser module can be miniaturized.

### BRIEF DESCRIPTION OF THE DRAWINGS

FIG. 1 is a perspective view showing an appearance of a laser module according to an embodiment.

FIG. 2 is a view schematically showing the configuration of the laser module shown in FIG. 1.

FIG. 3 is a view showing a metasurface lens and a stray light removal mask provided on the outer surface of the sealing member shown in FIG. 2.

FIG. 4 is a diagram for explaining the operation principle of the metasurface lens shown in FIG. 3.

FIG. 5 is a diagram for explaining a relationship between a position and a diameter of a columnar body included in the metasurface lens shown in FIG. 3.

FIG. 6 is a diagram showing a relationship between a diameter and a phase delay of the columnar body.

FIG. 7 is a diagram showing a relationship between a distance from the center of the metasurface lens shown in FIG. 3 and a phase delay.

FIG. 8 is a diagram for explaining a method for manufacturing the sealing body shown in FIG. 2.

FIG. 9 is a diagram for explaining a method for manufacturing the sealing body shown in FIG. 2.

FIG. 10 is a diagram schematically showing a configuration of a laser module according to a comparative example.

FIG. 11 is a diagram schematically showing a configuration of a laser module according to another embodiment.

FIG. 12 is a view showing a metasurface lens provided on the inner surface of the sealing member shown in FIG. 11.

FIG. 13 is a diagram for explaining the operation principle of the metasurface lens shown in FIG. 12.

FIG. 14 is a view showing a modification example of the sealing body.

FIG. 15 is a view showing another modification example of the sealing body.

### DETAILED DESCRIPTION

Hereinafter, embodiments of the present disclosure will be described in detail with reference to the drawings. In the description of the drawings, the same elements are denoted by the same reference numerals, and redundant description will be omitted. In each figure, an XYZ coordinate system may be shown. The Y-axis direction is a direction intersecting (for example, orthogonal to) the X-axis direction and the Z-axis direction. The Z-axis direction is a direction intersecting (for example, orthogonal to) the X-axis direction and the Y-axis direction.

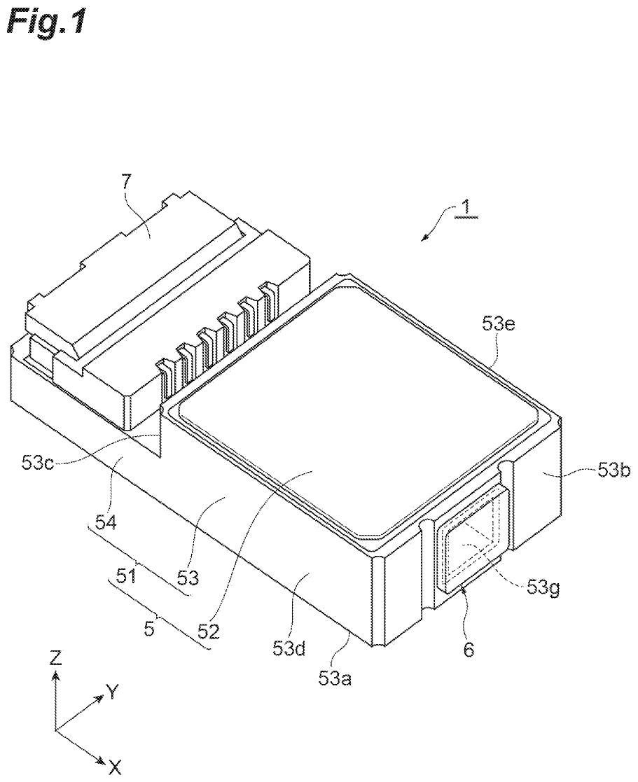

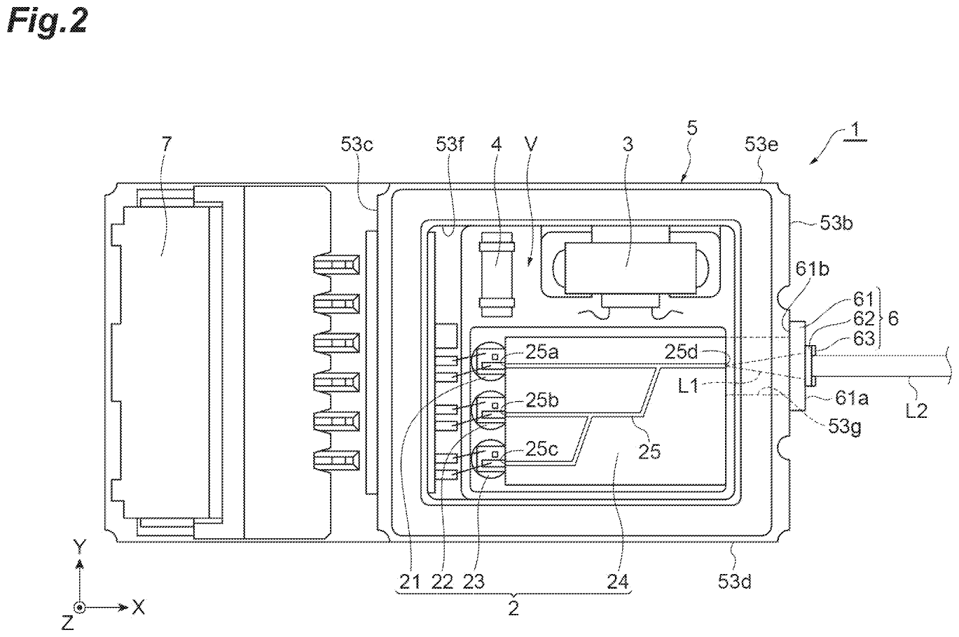

A laser module according to an embodiment will be described with reference to FIGS. 1 and 2. FIG. 1 is a perspective view showing an appearance of a laser module according to an embodiment. FIG. 2 is a view schematically showing the configuration of the laser module shown in FIG. 1.

A laser module 1 shown in FIGS. 1 and 2 is a module that generates laser light L2 by optically processing laser light L1 emitted from a light source unit 2 and emits the laser light L2. The laser module 1 is applied to for example, to a retinal projection device mounted on a near eye wearable device for superimposing an image on a field of view of the real world. Examples of such a near eye wearable device include smart glasses such as augmented reality (AR) glasses and mixed reality (MR) glasses. The laser module 1 includes the light source unit 2 (light source), a photodetector 3, a thermistor 4, a housing 5, a sealing body 6, and a connector 7.

The light source unit 2 emits the laser light L1. The light source unit 2 includes a red laser diode 21, a green laser diode 22, a blue laser diode 23, and a multiplexer 24. The red laser diode 21, the green laser diode 22, and the blue laser diode 23 are arranged in the Y-axis direction in this order. The multiplexer 24 multiplexes laser lights emitted from the three laser diodes into one laser light L1. In the present embodiment, the multiplexer 24 is a planar lightwave circuit (PLC). The multiplexer 24 includes an optical waveguide 25.

The optical waveguide 25 has an incident end 25a, an incident end 25b, an incident end 25c, and an emission end 25d. A laser light having a wavelength of red light is incident on the incident end 25a from the red laser diode 21. A laser light having a wavelength of green light is incident on the incident end 25b from the green laser diode 22. A laser light having a wavelength of blue light is incident on the incident end 25c from the blue laser diode 23. The optical waveguide 25 multiplexes laser lights emitted from the three laser diodes into one laser light L1, and emits the laser light L1 from the emission end 25d. The laser light L1 includes a component having a wavelength of red light (red component), a component having a wavelength of green light (green component), and a component having a wavelength of blue light (blue component).

The photodetector 3 is an element for detecting the optical power of the laser light L1. The photodetector 3 is arranged to be adjacent to the multiplexer 24. The photodetector 3 outputs the detected optical power to a laser driver (not shown). The thermistor 4 is an element for detecting the temperature of the light source unit 2. The thermistor 4 outputs the detected temperature to the laser driver (not shown). The laser driver drives the light source unit 2 based on, for example, the optical power of the laser light L1 and the temperature of the light source unit 2.

The housing 5 is a member defining an accommodation space V in which the light source unit 2, the photodetector 3, and the thermistor 4 are accommodated. The accommodation space V is filled with an inert gas. An example of an inert gas is nitrogen. The housing 5 is sealed so that inert gas in the accommodation space V does not leak to the outside of the housing 5. The housing 5 includes a main body 51 and a lid 52.

The main body 51 extends in the X-axis direction. The main body 51 is made of, for example, resin. The main body 51 includes an accommodating portion 53 having a box-like shape with its upper end open, and a mounting portion 54 on which the connector 7 is disposed. The accommodating portion 53 accommodates the light source unit 2, the photodetector 3 and the thermistor 4. The accommodating portion 53 includes a bottom wall 53a, a side wall 53b, a side wall 53c, a side wall 53d, and a side wall 53e.

The bottom wall 53a has a rectangular shape. The side walls 53b, 53c, 53d, and 53e are erected on the bottom wall 53a along the periphery of the bottom wall 53a. The side walls 53b and 53c face each other in the X-axis direction. The side walls 53d and 53e face each other in the Y-axis direction. Two side walls adjacent to each other among the side wall 53b, the side wall 53c, the side wall 53d, and the side wall 53e are connected so as to form a substantially right angle, and an opening 53f is formed by the upper ends of the side wall 53b, the side wall 53c, the side wall 53d, and the side wall 53e. An emission port 53g for emitting the laser light L1 is provided on the side wall 53b.

The mounting portion 54 is a plate-like portion that is provided on the side wall 53c and extends from the side wall 53c toward the side opposite to the side wall 53b. A stepped portion is formed by the side wall 53c and the mounting portion 54, and the connector 7 is disposed in the stepped portion.

The lid 52 hermetically seals the opening 53f of the accommodating portion 53. The lid 52 has a rectangular flat plate shape and is made of metal, for example. The accommodation space V is defined by the lid 52, the bottom wall 53a, the side wall 53b, the side wall 53c, the side wall 53d, and the side wall 53e.

The sealing body 6 is a member for hermetically sealing the emission port 53g. The sealing body 6 includes a sealing member 61, a metasurface lens 62 (first metasurface lens), and a stray light removal mask 63 (mask).

The sealing member 61 is a substrate having visible light transparency through which visible light passes. That is, the sealing member 61 is a transparent substrate. As the constituent material of the sealing member 61, a material having visible light transparency and having a refractive index greater than 1 is used. Examples of such constituent materials include silicon oxides (e.g., SiO₂), titanium oxides (e.g., TiO₂), silicon nitrides (e.g., SiN), and titanium nitrides (e.g., TiN). The sealing member 61 hermetically seals the emission port 53g and allows the laser light L1 emitted from the emission end 25d to pass therethrough.

The sealing member 61 has an outer surface 61a (first surface) and an inner surface 61b (second surface). The outer surface 61a and the inner surface 61b are main surfaces intersecting the emission direction of the laser light L1. In the present embodiment, the emission direction of the laser light L1 is the X-axis direction. The outer surface 61a faces the outside of the housing 5. The inner surface 61b is a surface opposite to the outer surface 61a, and covers the emission port 53g.

The metasurface lens 62 is a member that functions as a collimating lens. The metasurface lens 62 is provided on the outer surface 61a. The term “metasurface lens” is a general term for a metasurface that functions as a lens, and is simply referred to as a “meta-lens”. The stray light removal mask 63 is a mask for removing a part of light (stray light) emitted from the metasurface lens 62. The stray light removal mask 63 is provided in the metasurface lens 62. Details of the metasurface lens 62 and the stray light removal mask 63 will be described later.

The connector 7 is a member for connecting a cable that connects the laser module 1 to the laser driver (not shown). The connector 7 is, for example, a flexible printed circuit (FPC) connector.

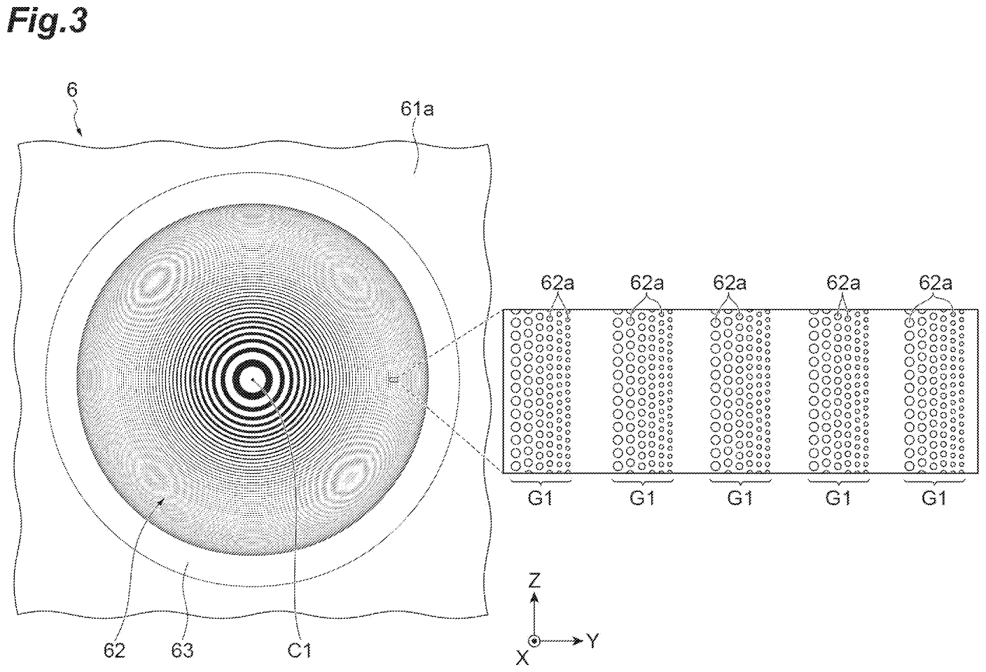

Next, the metasurface lens 62 and the stray light removal mask 63 will be described in detail with reference to FIG. 3. FIG. 3 is a view showing a metasurface lens and a stray light removal mask provided on the outer surface of the sealing member shown in FIG. 2.

As shown in FIG. 3, the metasurface lens 62 has a circular shape in a plan view. The diameter of the metasurface lens 62 is, for example, about 5 mm. The metasurface lens 62 includes a plurality of columnar bodies 62a. Each columnar body 62a is a columnar member having visible light transparency. That is, each columnar body 62a is a transparent columnar member in the visible light region. As the constituent material of the columnar body 62a, a material having visible light transparency and a refractive index greater than 1 is used. Examples of such constituent materials include silicon oxides (e.g., SiO₂), titanium oxides (e.g., TiO₂), silicon nitrides (e.g., SiN), and titanium nitrides (e.g., TiN). The refractive index of the columnar body 62a is greater than 1. From the viewpoint of process efficiency, the refractive index of the columnar body 62a is 2.5 or less, for example.

In the present embodiment, each columnar body 62a has a cylindrical shape. The shape of each columnar body 62a is not limited to a cylinder, but may be a rectangular column. The shape of each columnar body 62a may be a truncated cone shape or a truncated pyramid shape with a tapered tip. Each of the columnar bodies 62a is erected on the outer surface 61a. That is, each columnar body 62a extends from the outer surface 61a in the emission direction of the laser light L1. The height (the length in the emission direction of the laser light L1) of each columnar body 62a is, for example, 1000 nm or more and 2000 nm or less.

The plurality of columnar bodies 62a are aligned concentrically around a center point C1 of the metasurface lens 62. The center point C1 faces the emission end 25d, and is closest to the emission end 25d in the metasurface lens 62. The plurality of columnar bodies 62a located on the same circle are arranged at equal intervals, and the shortest distance between the outer peripheral surfaces of two adjacent columnar bodies 62a is about half the wavelength λ of the laser light L1.

The cross-sectional area of each columnar body 62a intersecting (for example, orthogonal to) the emission direction of the laser light L1 is set in accordance with the position of the columnar body 62a so that the metasurface lens 62 has a desired lens function. The above-described cross-sectional areas of the columnar bodies 62a located at an equal distance from the center point C1 (that is, the columnar bodies 62a located on the same circle) are the same. The plurality of columnar bodies 62a is arranged with a periodic change in the above-described cross-sectional areas in a direction away from the center point C1.

In the present embodiment, the plurality of columnar bodies 62a are divided into a plurality of annular groups G1 centered on the center point C1. The shortest distance between the outer peripheral surfaces of two adjacent columnar bodies 62a among the plurality of columnar bodies 62a included in the same group G1 is about half the wavelength λ of the laser light L1. In the same group G1, the above-described cross-sectional area of the columnar body 62a is smaller as the columnar body 62a is located further from the center point C1. The above-described cross-sectional area of the columnar body 62a located on the inner periphery of one group G1 is substantially the same as the above-described cross-sectional area of the columnar body 62a located on the inner periphery of another group G1. The above-described cross-sectional area of the columnar body 62a located on the outer periphery of one group G1 is substantially the same as the above-described cross-sectional area of the columnar body 62a located on the outer periphery of another group G1.

The stray light removal mask 63 is provided in a circular (annular) shape along the outer peripheral edge of the metasurface lens 62, and covers a region along the outer peripheral edge of the metasurface lens 62. The stray light removal mask 63 covers a region extending from the outer peripheral edge of the metasurface lens 62 toward the center point C1 by about 10% to 50% of the diameter of the metasurface lens 62. As a constituent material of the stray light removal mask 63, a material which blocks visible light and has a low reflectance is used. Examples of such constituent materials include silicon (Si), titanium (Ti), and gold (Au). The stray light removal mask 63 has a film thickness (length in the emission direction of the laser light L1) of, for example, 100 nm or more and 1000 nm or less.

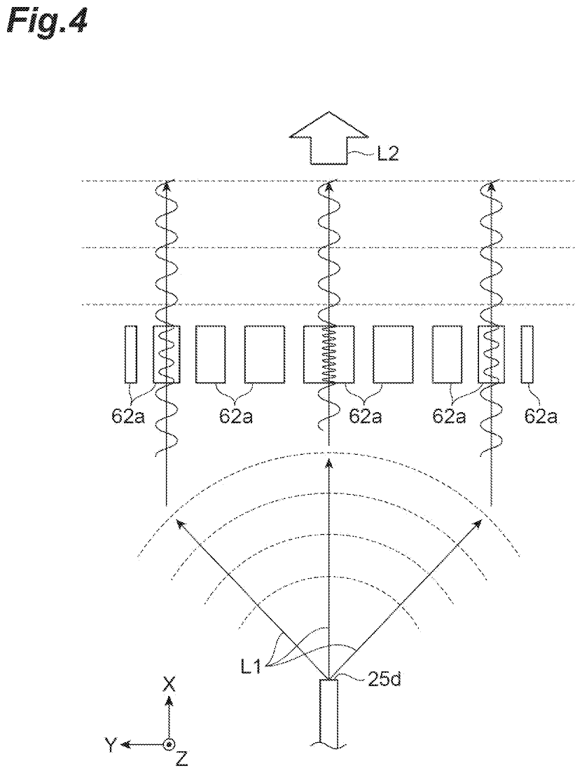

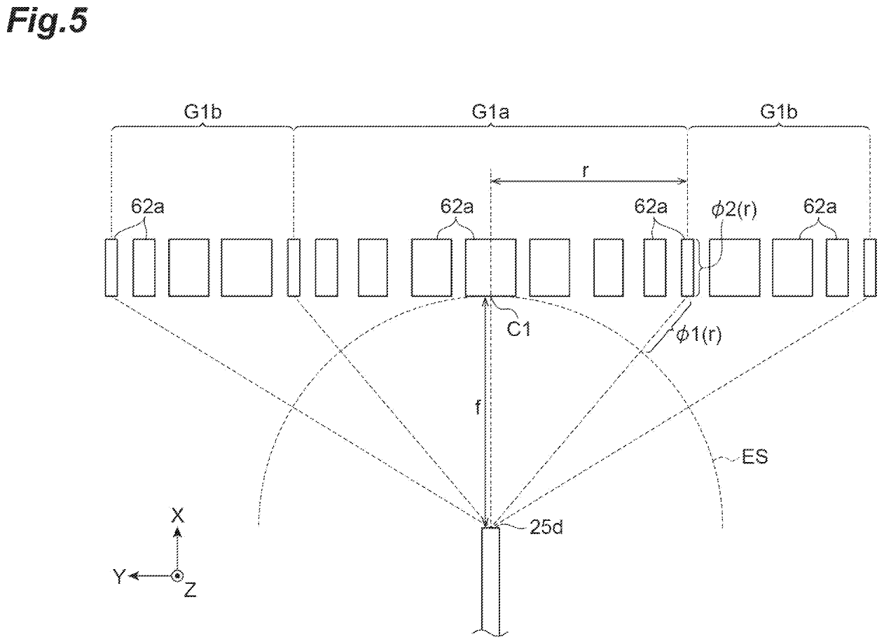

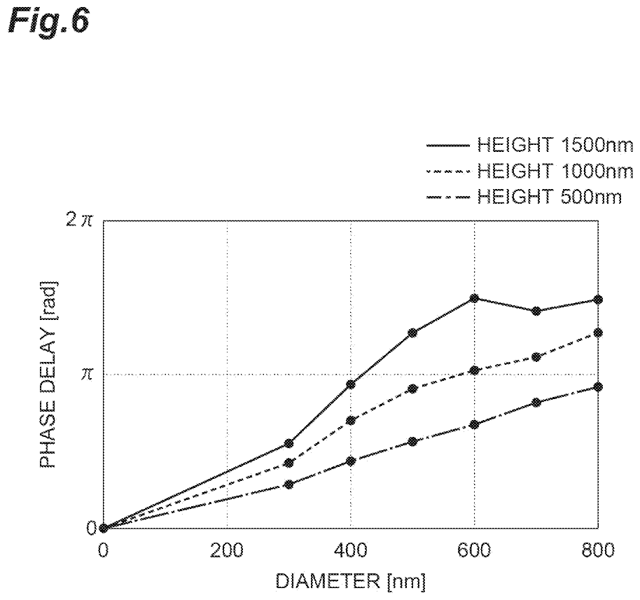

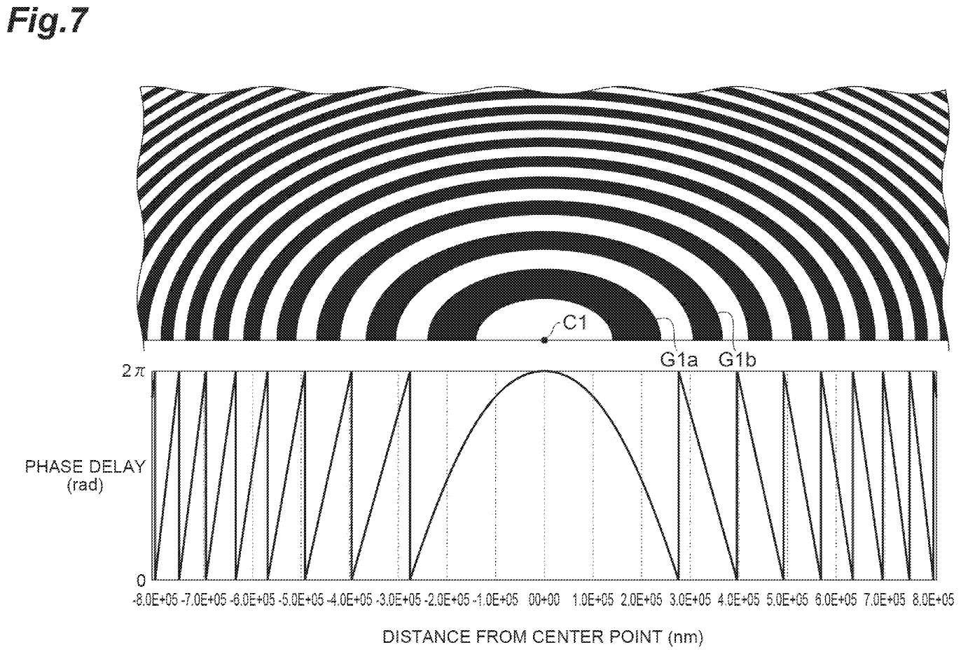

Next, the operation principle of the metasurface lens 62 will be described with reference to FIGS. 4 to 7. FIG. 4 is a diagram for explaining the operation principle of the metasurface lens shown in FIG. 3. FIG. 5 is a diagram for explaining a relationship between a position and a diameter of a columnar body included in the metasurface lens shown in FIG. 3. FIG. 6 is a diagram showing a relationship between a diameter and a phase delay of the columnar body. FIG. 7 is a diagram showing a relationship between a distance from the center of the metasurface lens shown in FIG. 3 and a phase delay. In the present embodiment, since each columnar body 62a has a cylindrical shape, the diameter of the cylinder will be used instead of the above-described cross-sectional area.

As shown in FIG. 4, the laser light L1 emitted from the emission end 25d propagates as a spherical wave. When the laser light L1 passes through the columnar body 62a of the metasurface lens 62, a phase delay corresponding to the diameter of the columnar body 62a occurs. Therefore, the diameter of each columnar body 62a is adjusted so as to obtain a desired lens function. In the present embodiment, the diameter of each columnar body 62a is set so that the phase delay occurring from when the laser light L1 is emitted from the emission end 25d to when the laser light L1 has passed through each columnar body 62a is the same regardless of which position of the metasurface lens 62 the laser beam L1 passes through. According to this configuration, the laser light L1 passes through the metasurface lens 62 to be converted into the laser light L2 which is a collimated light. That is, the metasurface lens 62 functions as a collimating lens.

Here, a method for determining the diameter of the columnar body 62a will be specifically described. As shown in FIG. 5, the phase of the laser light L1 that has reached each columnar body 62a is delayed from the phase of the laser light L1 that has reached the center point C1, and the phase delay φ1(r), which is the delay amount, increases as the distance between each columnar body 62a and the emission end 25d increases. In the present embodiment, in order for the metasurface lens 62 to function as a collimating lens, the diameter of each columnar body 62a is determined so that the sum of the phase delay φ1(r) and the phase delay φ2 (r) occurring in the columnar body 62a becomes a constant delay amount Φ in all the columnar bodies 62a.

The phase delay φ1(r) can be regarded as a phase delay corresponding to the distance from the equiphase plane ES of the spherical wave to each columnar body 62a, and changes in accordance with the distance r. The equiphase plane ES is an equiphase plane around the emission end 25d with a radius having the same length as the focal length f. The focal length f is a distance from the emission end 25d to the center point C1. The distance r is a distance from the center point C1 to the central axis of the columnar body 62a.

The phase delay φ1(r) is expressed by Equation (1) using the focal length f, the distance r, and the wavelength λ of the laser light L1.

### [Equation 1]

$$φ1 ( r ) = \frac{2 π}{λ} ( \sqrt{{r}^{2} + {f}^{2}} - f ) \qquad ( 1 )$$

The phase delay φ2(r) is a phase delay occurring in the columnar body 62a located at the distance r. As shown in FIG. 6, the phase delay φ2(r) changes in accordance with the diameter and the height of the columnar body 62a. The horizontal axis in FIG. 6 indicates the diameter (unit: nm) of the columnar body 62a, and the vertical axis in FIG. 6 indicates the phase delay (unit: radian). The characteristics shown in FIG. 6 are characteristics calculated in advance by numerical calculation with the refractive index set to 1.5. In the columnar bodies 62a having the same height, the phase delay tends to be larger as the diameter of the columnar body 62a is larger. In the columnar bodies 62a having the same diameter, the phase delay tends to be larger as the height of the columnar body 62a is larger.

If the height of the columnar body 62a is too low, the phase delay does not change much even if the diameter of the columnar body 62a is changed. If the height of the columnar body 62a is too high, the amount of change in the phase delay is larger than the amount of change in the diameter of the columnar body 62a, so that the dimensional accuracy of the columnar body 62a is required. Therefore, as described above, the height of the columnar body 62a is set to, for example, 1000 nm or more and 2000 nm or less.

There is a case where the sum of the phase delay φ1(r) and the phase delay φ2(r) exceeds 2π radians. In this case, since the phase of light has a periodicity of every 2π radians, the diameter of each columnar body 62a is determined so that the remainder obtained by dividing the sum of the phase delay φ1(r) and the phase delay φ2(r) by 2π radians is equal to the delay amount Φ in all the columnar bodies 62a. That is, the relationship shown by Equation (2) is established between the phase delay φ1(r) and the phase delay φ2(r). Note that the function MOD (A, B) is a function that returns a remainder obtained by dividing A by B.

[Equation 2]

ϕ=MOD(φ1(r)+φ2(r),2π) (2)

The height and the diameter of each columnar body 62a are determined from the characteristics shown in FIG. 6 so as to obtain a phase delay φ2(r) satisfying the relationship of Equation (2). In the present embodiment, in order to facilitate manufacturing of the metasurface lens 62, all the columnar bodies 62a included in the metasurface lens 62 are set to the same height. Therefore, the diameter of each columnar body 62a is determined from the characteristics shown in FIG. 6 so as to obtain the phase delay φ2(r) satisfying the relationship of Equation (2).

As shown in FIG. 7, the phase delay φ2(0) at the center point C1 is set to 2π radians (0 radians). The horizontal axis in FIG. 7 represents the distance (unit: nm) from the center point C1, and the vertical axis in FIG. 7 represents the phase delay φ2(r) (unit: radian). In the vicinity of the center point C1 (group G1a), the diameter of each columnar body 62a is set so that the sum of the phase delay φ1(r) and the phase delay φ2(r) is equal to 2π radians. Since the phase delay φ1(r) increases as the distance r increases, the phase delay φ2(r) gradually decreases from 2π radians, and the diameter of the columnar body 62a also decreases.

The phase delay φ2(r) cannot be made smaller than 0 radians. Therefore, when the phase delay φ1(r) exceeds 2π radians, the diameter of each columnar body 62a is set so that the sum of the phase delay φ1(r) and the phase delay φ2(r) is equal to 4π radians. The columnar body 62a whose diameter is set so that the sum of the phase delay φ1(r) and the phase delay φ2(r) is equal to 4π radians belongs to the group G1b. Thereafter, each time the phase delay φ1(r) exceeds a multiple of 2π radians, the target value of the sum of the phase delay φ1(r) and the phase delay φ2(r) is increased by 2π radians.

In the example shown in FIG. 6, since there is no diameter of the columnar body 62a such that the phase delay φ2(r) ranges from 0π radians to 0.5π radians and from 1.5π radians to 2π radians, the columnar body 62a may not be provided for the phase delay φ2(r) in these ranges. In the present embodiment, as shown in FIGS. 3 and 7, the plurality of columnar bodies 62a are divided into a plurality of annular groups G1 having the center point C1 as a center, and a region in which the columnar bodies 62a are not provided exists between two adjacent groups G1.

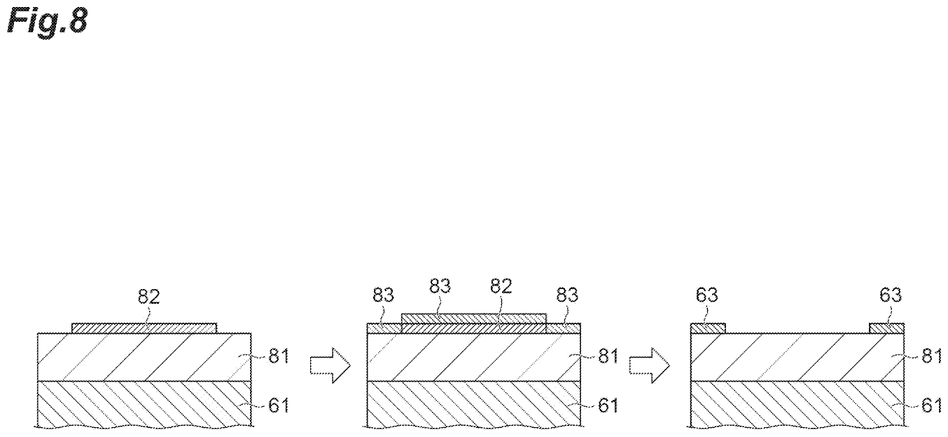

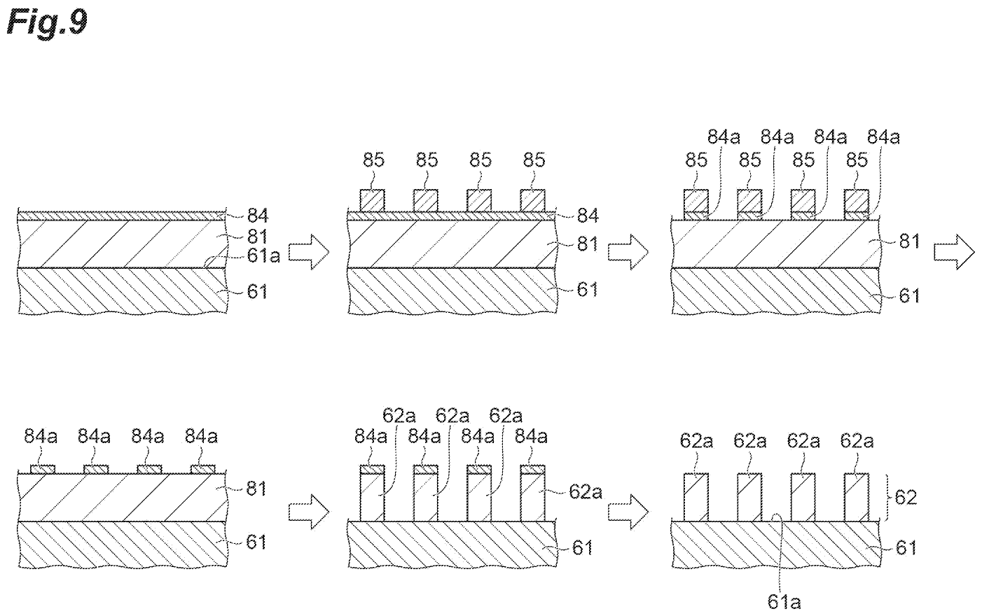

Next, a method for manufacturing the sealing body 6 will be described with reference to FIGS. 8 and 9. FIGS. 8 and 9 are diagrams for explaining a method for manufacturing the sealing body shown in FIG. 2. As shown in FIG. 8, a base body in which a light-transmitting layer 81 which is a base of the metasurface lens 62 formed on an outer surface 61a of the sealing member 61 is prepared. The light-transmitting layer 81 is a layer made of a material having visible light transparency. The sealing member 61 and the light-transmitting layer 81 may be made of the same material. In this case, a base body in which the sealing member 61 and the light-transmitting layer 81 are integrated is prepared.

Subsequently, a resist mask 82 is formed on the light-transmitting layer 81. The resist mask 82 is formed so as to cover a region where the metasurface lens 62 is formed on the upper surface of the light-transmitting layer 81.

Subsequently, a stray light removal film 83, which is a base of the stray light removal mask 63, is formed. The stray light removal film 83 is formed on the resist mask 82 and on a portion of the upper surface of the light-transmitting layer 81 which is not covered with the resist mask 82. Then, the resist mask 82 is removed by the lift-off method. As a result, the stray light removal mask 63 is formed on the light-transmitting layer 81.

Subsequently, as shown in FIG. 9, a metal layer 84 is formed on the light-transmitting layer 81. The metal layer 84 is formed on a portion of the upper surface of the light-transmitting layer 81 which is not covered with the stray light removal mask 63. Specifically, the metal layer 84 is formed by vacuum film deposition using a technique such as a direct current (DC) sputtering. A metal material composed of, for example, chromium (Cr) is used for forming the metal layer 84.

Subsequently, a resist pattern 85 is formed on the metal layer 84 by a photolithographic process. Specifically, a liquid resist is applied onto the metal layer 84 using a spin coater or the like, and the applied liquid resist is dried to form a resist film (photoresist). Then, the resist pattern 85 corresponding to the columnar body 62a is transferred onto the resist film using an exposure device such as a KrF exposure device and an electron beam lithography device. Then, the resist pattern 85 transferred to the resist film is developed using a developing machine.

Subsequently, the portion of the metal layer 84 not covered by the resist pattern 85 is removed by an etching process, and then the resist pattern 85 is removed. As a result, metal masks 84a are formed on the light-transmitting layer 81.

Subsequently, the portion of the light-transmitting layer 81 not covered with the metal masks 84a is removed by an etching process, and then the metal masks 84a are removed. As a result, the columnar bodies 62a are formed on the outer surface 61a of the sealing member 61. As described above, the sealing body 6 is manufactured.

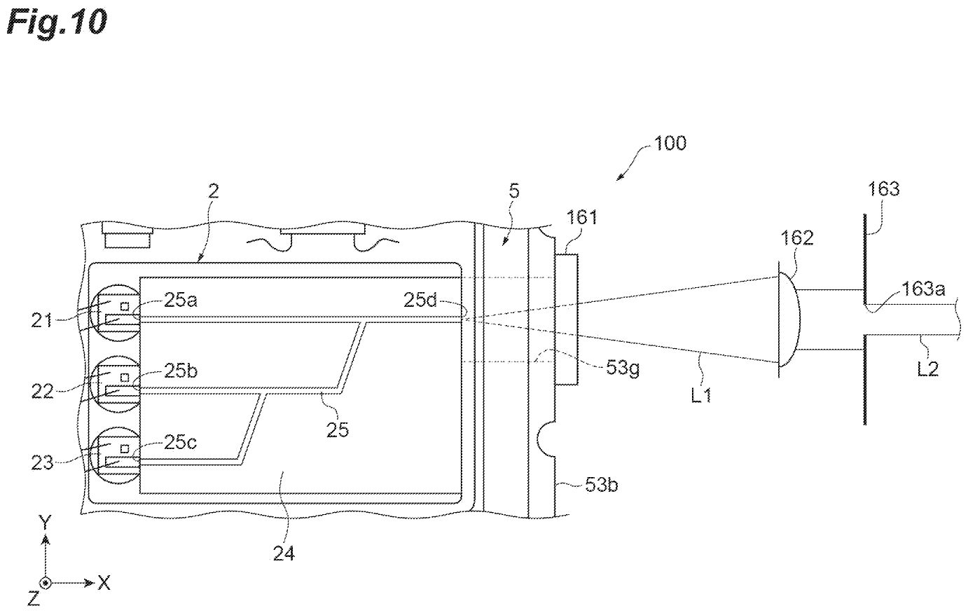

Next, the operation and effect of the laser module 1 will be described with reference to FIGS. 2 and 10 in comparison with the laser module of the comparative example. FIG. 10 is a diagram schematically showing a configuration of a laser module according to a comparative example. A laser module 100 shown in FIG. 10 is different from the laser module 1 mainly in that the laser module 100 includes a sealing member 161, a collimating lens 162 and a stray light removal pinhole 163 in place of the sealing body 6.

The sealing member 161 is a substrate having visible light transparency through which visible light passes. The sealing member 161 hermetically seals the emission port 53g and allows the laser light L1 emitted from the emission end 25d to pass therethrough. The collimating lens 162 is a lens for converting the laser light L1 that has passed through the sealing member 161 into collimated light. The stray light removal pinhole 163 is a member for removing stray light from the collimated light emitted from the collimating lens 162 to generate the laser light L2. The stray light removal pinhole 163 is a plate-shaped member provided with a circular through hole 163a in a plan view.

In the laser module 100, the collimating lens 162 and the stray light removal pinhole 163 are independent components separate from the sealing member 161. Thus, the laser module 100 further includes components (not shown) that hold the collimating lens 162 and the stray light removal pinhole 163. Therefore, the number of components constituting the laser module 100 is large. Since the numerical aperture of the collimating lens 162 is large, the focal length between the emission end 25d and the collimating lens 162 is long. Therefore, there is a possibility that the size of the laser module 100 is increased.

On the other hand, in the laser module 1, the metasurface lens 62 is provided on the outer surface 61a of the sealing member 61 that seals the emission port 53g of the housing 5. In other words, since the sealing member 61 and the metasurface lens 62 are integrated, any separate component for holding the metasurface lens 62 is not required. Therefore, compared with the laser module 100, the number of components constituting the laser module 1 can be reduced. Further, since the focal length of the metasurface lens 62 is adjustable, the distance between the emission end 25d of the light source unit 2 and the metasurface lens 62 can be shortened. As a result, the laser module 1 can be made smaller in size than the laser module 100.

In the laser module 1, the stray light removal mask 63 is provided on the metasurface lens 62. In other words, since the sealing member 61, the metasurface lens 62, and the stray light removal mask 63 are integrated, any separate component for holding the stray light removal mask 63 is not required. Therefore, compared with the laser module 100, the number of components constituting the laser module 1 can be further reduced, and the laser module 1 can be further miniaturized. That is, stray light can be removed without increasing the size of the laser module 1.

The metasurface lens 62 functions as a collimating lens. Therefore, the laser light L1 emitted from the light source unit 2 can be converted into collimated light without increasing the size of the laser module 1.

The metasurface lens 62 includes the plurality of columnar bodies 62a having visible light transparency. By the laser light L1 passing through the columnar body 62a, a phase delay occurs in the laser light L1. Therefore, by appropriately adjusting the phase delay occurring in each columnar body 62a, the collimating lens function can be obtained.

As the cross-sectional area (diameter) of the columnar body 62a intersecting the emission direction of the laser light L1 is larger, the phase delay of the laser light L1 occurring in the columnar body 62a is larger. Therefore, the collimating lens function can be obtained by appropriately setting the above-described cross-sectional area (diameter) in accordance with the position of the columnar body 62a.

In the laser module 1, the metasurface lens 62 is provided on the outer surface 61a of the sealing member 61. This makes it possible to keep the metasurface lens 62 away from the light source unit 2 (emission end 25d) compared with the configuration in which the metasurface lens 62 is provided on the inner surface 61b of the sealing member 61. Therefore, the beam diameter of the laser light L1 that has reached the metasurface lens 62 can be increased.

The plurality of columnar bodies 62a are aligned concentrically around the center point C1, and the plurality of columnar bodies 62a are arranged with a periodic change in the cross-sectional areas (diameters) in a direction away from the center point C1. Since the phase delay φ2(r) increases with distance from the center point C1, the collimating lens function of the metasurface lens 62 can be realized. However, as shown in FIG. 6, the range in which the phase delay φ2(r) can be changed is limited. Since the phase of light has a periodicity of every 2π radians, the collimating lens function can be realized by a periodic change in the diameters of the columnar bodies 62 in a direction away from the center point C1.

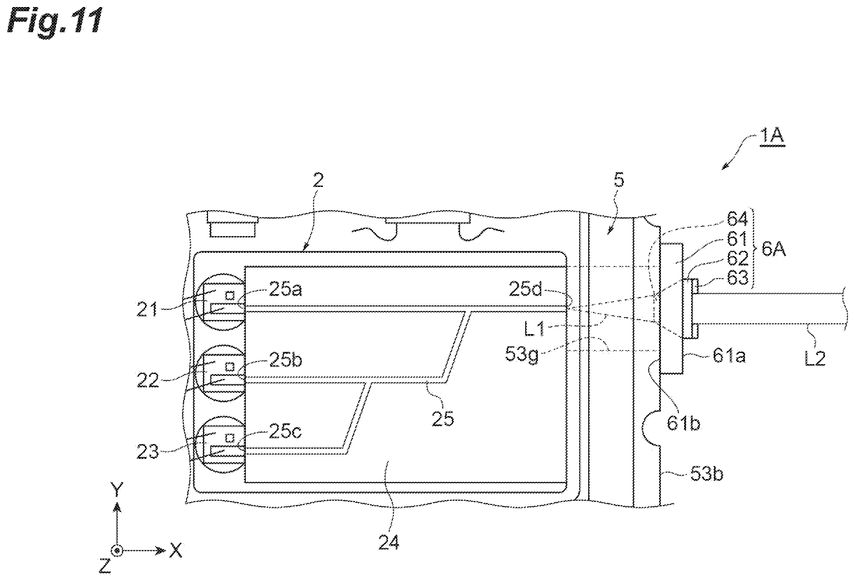

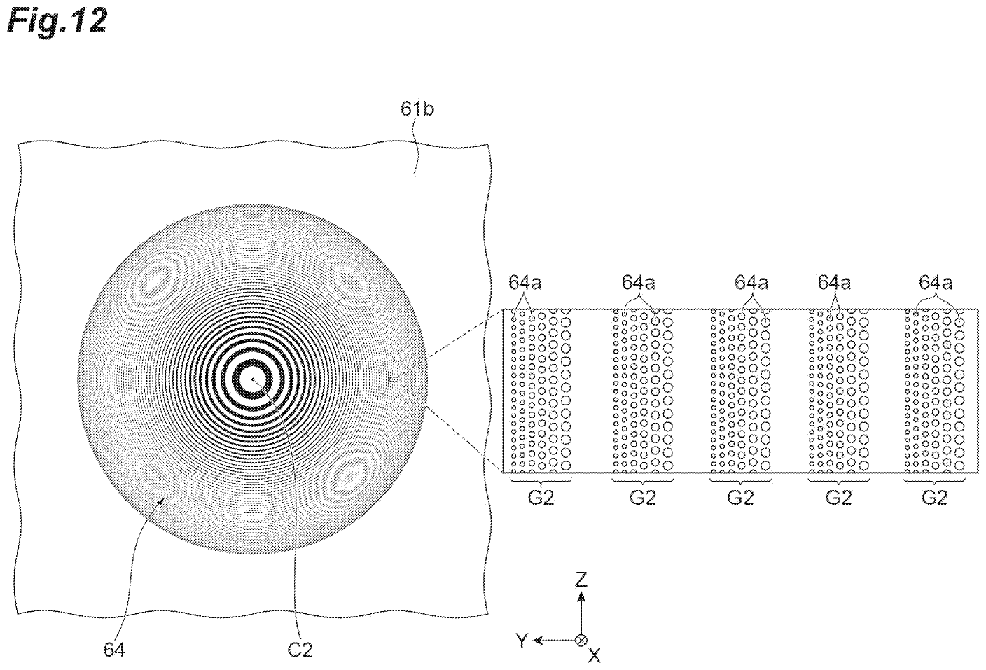

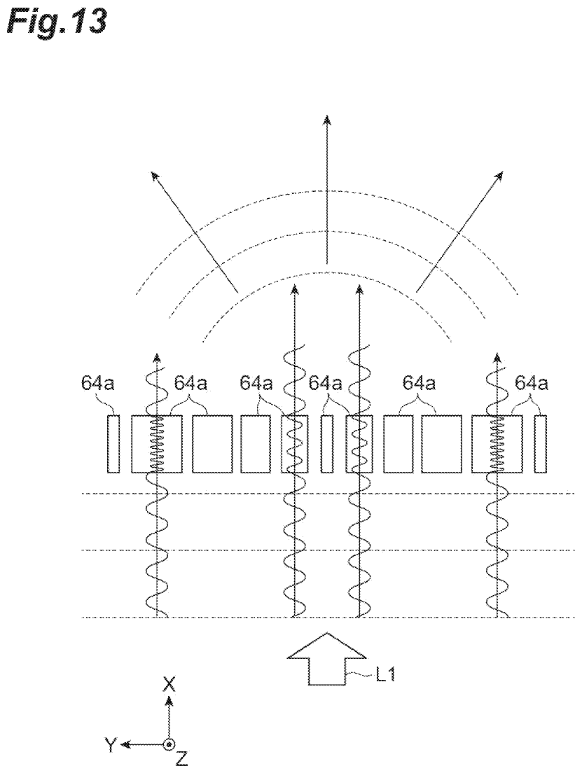

Next, a laser module according to another embodiment will be described with reference to FIGS. 11 to 13. FIG. 11 is a diagram schematically showing a configuration of a laser module according to another embodiment. FIG. 12 is a view showing a metasurface lens provided on the inner surface of the sealing member shown in FIG. 11. FIG. 13 is a diagram for explaining the operation principle of the metasurface lens shown in FIG. 12. A laser module 1A shown in FIG. 11 is different from the laser module 1 mainly in that the laser module 1A includes a sealing body 6A instead of the sealing body 6. The sealing body 6A is different from the sealing body 6 mainly in that the sealing body 6A further includes a metasurface lens 64 (second metasurface lens).

The metasurface lens 64 is a member that functions as a beam expander. The metasurface lens 64 is provided on the inner surface 61b. As shown in FIG. 12, the metasurface lens 64 has a circular shape in a plan view. The diameter of the metasurface lens 64 is shorter than the diameter of the metasurface lens 62, for example, about 0.5 mm. The metasurface lens 64 includes a plurality of columnar bodies 64a. Each columnar body 64a is a columnar member having visible light transparency. That is, each columnar body 64a is a transparent columnar member in the visible light region. Since the constituent material of the columnar body 64a is the same as that of the columnar body 62a, a detailed description thereof will be omitted.

In the present embodiment, each columnar body 64a has the same cylindrical shape as the columnar body 62a. Each of the columnar bodies 64a is erected on the inner surface 61b. That is, each columnar body 64a extends from the inner surface 61b toward the accommodation space V in the emission direction of the laser light L1. The height (the length in the emission direction of the laser light L1) of each columnar body 64a is, for example, 1000 nm or more and 2000 nm or less.

The plurality of columnar bodies 64a are aligned concentrically around a center point C2 of the metasurface lens 64. The plurality of columnar bodies 64a located on the same circle are arranged at equal intervals, and the shortest distance between the outer peripheral surfaces of two adjacent columnar bodies 64a is about half the wavelength λ of the laser light L1. The cross-sectional area of each columnar body 64a intersecting (for example, orthogonal to) the emission direction of the laser light L1 is set in accordance with the position of the columnar body 64a so that the metasurface lens 64 has a desired lens function. The above-described cross-sectional areas of the columnar bodies 64a located at an equal distance from the center point C2 (that is, the columnar bodies 64a located on the same circle) are the same. The plurality of columnar bodies 64a are arranged with a periodic change in the above-described cross-sectional areas in a direction away from the center point C2.

In the present embodiment, the plurality of columnar bodies 64a is divided into a plurality of annular groups G2 centered on the center point C2. The shortest distance between the outer peripheral surfaces of two adjacent columnar bodies 64a among the plurality of columnar bodies 64a included in the same group G2 is about half the wavelength λ of the laser light L1. In the same group G2, the above-described cross-sectional area of the columnar body 64a is larger as the columnar body 64a is located further from the center point C2. The above-described cross-sectional area of the columnar body 64a located on the inner periphery of one group G2 is substantially the same as the above-described cross-sectional area of the columnar body 64a located on the inner periphery of another group G2. The above-described cross-sectional area of the columnar body 64a located on the outer periphery of one group G2 is substantially the same as the above-described cross-sectional area of the columnar body 64a located on the outer periphery of another group G2.

Since each columnar body 64a has a cylindrical shape, the operation principle of the metasurface lens 64 will be described by using the diameter of the cylinder instead of the above-described cross-sectional area. The laser light L1 emitted from the emission end 25d of the multiplexer 24 propagates as a spherical wave. For convenience of description, in FIG. 13, the laser light L1 is depicted as collimated light, but actually propagates so as to spread spherically from the emission end 25d.

When the laser light L1 passes through the columnar body 64a of the metasurface lens 64, a phase delay corresponding to the diameter of the columnar body 64a occurs. Therefore, the diameter of each columnar body 64a is adjusted so as to obtain a desired lens function. In the present embodiment, the diameter of each columnar body 64a is set so that the phase delay occurring from when the laser light L1 is emitted from the emission end 25d to when the laser light L1 has passed through each columnar body 64a increases with distance from the center point C2. According to this configuration, the divergence angle of the laser light L1 is increased by the laser light L1 passing through the metasurface lens 64, and the beam diameter of the laser light L1 that has reached the metasurface lens 62 is increased. That is, the metasurface lens 64 functions as a beam expander.

The diameter of the columnar body 64a is determined so as to obtain, for example, a relationship obtained by vertically inverting the relationship shown in FIG. 7. That is, the height and the diameter of each columnar body 64a are determined from the characteristics shown in FIG. 6 so as to obtain the phase delay φ2(r) satisfying the relationship obtained by vertically inverting the relationship shown in FIG. 7. In the present embodiment, in order to facilitate manufacturing of the metasurface lens 64, all the columnar bodies 64a included in the metasurface lens 64 are set to the same height. Therefore, the diameter of each columnar body 64a is determined from the characteristics shown in FIG. 6 so as to obtain the phase delay φ2(r) satisfying the relationship obtained by vertically inverting the relationship shown in FIG. 7.

In the laser module 1A, the same effects as those of the laser module 1 can be obtained in the configuration common to the laser module 1. In the laser module 1A, the metasurface lens 64 functioning as a beam expander is provided on the inner surface 61b of the sealing member 61. According to this configuration, the laser light L1 can be incident on the metasurface lens 62 after the divergence angle of the laser light L1 is increased. Therefore, since the beam diameter of the laser light L1 that has reached the metasurface lens 62 can be adjusted, the distance between the emission end 25d and the metasurface lens 62 can be further shortened. As a result, the laser module 1A can be further miniaturized.

The laser module according to the present disclosure is not limited to the above-described embodiments.

For example, the laser modules 1 and 1A may be applied to devices other than the retinal projection device. The laser light L1 may be a laser light other than visible light. In this case, the sealing member 61 and the columnar bodies 62a have optical transparency allowing the laser light L1 to pass therethrough.

The metasurface lens 62 may be configured to function as a lens other than a collimating lens. The metasurface lens 62 may be configured, for example, to function as a condenser lens, or may be configured to function as a beam expander.

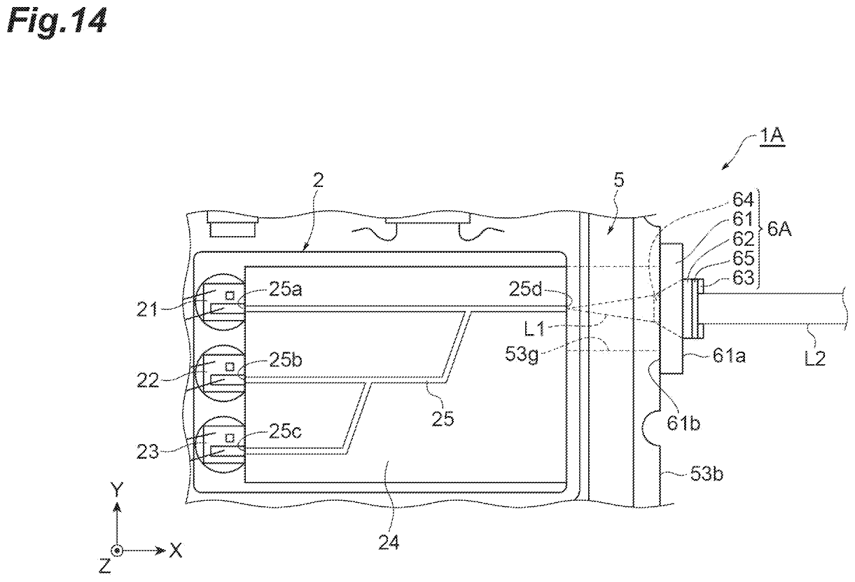

As shown in FIG. 14, the sealing body 6A may further include a cover layer 65 covering the metasurface lens 62. Similarly, the sealing body 6 may further include a cover layer 65 covering the metasurface lens 62. The cover layer 65 is provided on the distal end surfaces of the plurality of columnar bodies 62a. The cover layer 65 may be further provided in a gap between the plurality of columnar bodies 62a. As a constituent material of the cover layer 65, a material having a low refractive index close to the refractive index of air is used. An example of such a constituent material is acrylic resin. According to this configuration, since the metasurface lens 62 is covered with the cover layer 65, the metasurface lens 62 is not exposed to the outside air. This makes it possible to reduce the possibility that the metasurface lens 62 is stained or damaged.

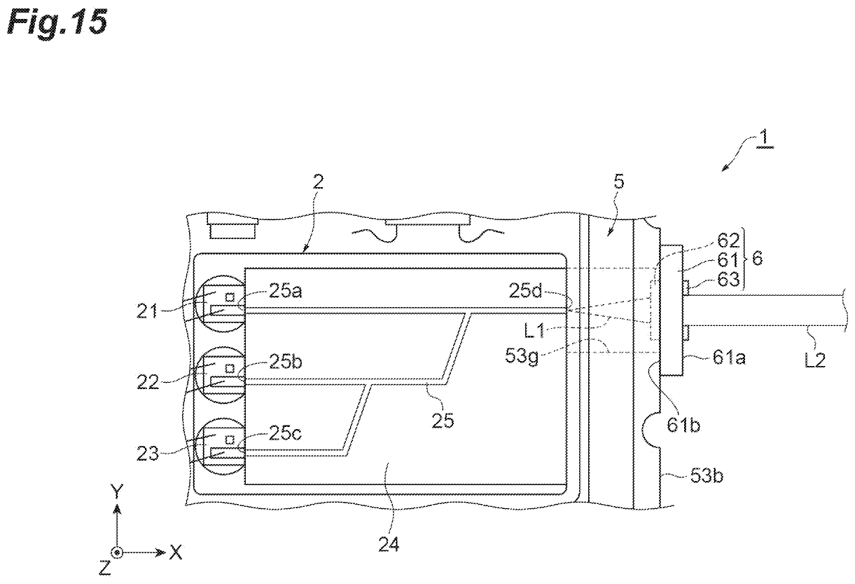

As shown in FIG. 15, the metasurface lens 62 may be provided on the inner surface 61b (first surface) instead of the outer surface 61a (second surface). In this case, the stray light removal mask 63 is provided on the outer surface 61a. According to this configuration, since the metasurface lens 62 is located in the sealed accommodation space V, the metasurface lens 62 is not exposed to the outside air. This makes it possible to reduce the possibility that the metasurface lens 62 is stained or damaged.

### (Additional Statements)

[Clause 1]

A laser module comprising:
a light source configured to emit laser light;
a housing configured to accommodate the light source, the housing provided with an emission port through which the laser light is emitted;
a sealing member having optical transparency, the sealing member configured to seal the emission port, the sealing member having a first surface and a second surface intersecting an emission direction of the laser light; and a first metasurface lens provided on the first surface.

[Clause 2]

The laser module according to clause 1,
wherein the first metasurface lens comprises a plurality of columnar bodies having optical transparency.

[Clause 3]

The laser module according to clause 2,
wherein a cross-sectional area intersecting the emission direction of each of the plurality of columnar bodies is set in accordance with a position of a columnar body.

[Clause 4]

The laser module according to clause 3,
wherein the plurality of columnar bodies is concentrically aligned, and
wherein the plurality of columnar bodies is arranged with a periodic change in the cross-sectional areas of the plurality of columnar bodies in a direction away from a center point of the concentric circle.

[Clause 5]

The laser module according to any one of clauses 1 to 4,
wherein the first metasurface lens functions as a collimating lens.

[Clause 6]

The laser module according to any one of clauses 1 to 5,
wherein the second surface is an inner surface covering the emission port, and
wherein the first surface is an outer surface opposite to the inner surface.

[Clause 7]

The laser module according to clause 6, further comprising a second metasurface lens provided on the second surface,
wherein the second metasurface lens functions as a beam expander.

[Clause 8]

The laser module according to clause 6 or 7, further comprising a cover layer covering the first metasurface lens.

[Clause 9]

The laser module according to any one of clauses 1 to 5,
wherein the first surface is an inner surface covering the emission port, and
wherein the second surface is an outer surface opposite to the inner surface.

[Clause 10]

The laser module according to any one of clauses 1 to 9, further comprising a mask configured to remove a part of light emitted from the first metasurface lens.

What is claimed is:

1. A laser module comprising:
a light source configured to emit laser light;
a housing configured to accommodate the light source, the housing provided with an emission port through which the laser light is emitted;
a sealing member having optical transparency, the sealing member configured to seal the emission port, the sealing member having a first surface and a second surface intersecting an emission direction of the laser light; and
a first metasurface lens provided on the first surface.

2. The laser module according to claim 1,
wherein the first metasurface lens comprises a plurality of columnar bodies having optical transparency.

3. The laser module according to claim 2,
wherein a cross-sectional area intersecting the emission direction of each of the plurality of columnar bodies is set in accordance with a position of a columnar body.

4. The laser module according to claim 3,
wherein the plurality of columnar bodies is concentrically aligned, and
wherein the plurality of columnar bodies is arranged with a periodic change in the cross-sectional areas of the plurality of columnar bodies in a direction away from a center point of the concentric circle.

5. The laser module according to claim 1,
wherein the first metasurface lens functions as a collimating lens.

6. The laser module according to claim 1,
wherein the second surface is an inner surface covering the emission port, and
wherein the first surface is an outer surface opposite to the inner surface.

7. The laser module according to claim 6, further comprising a second metasurface lens provided on the second surface,
wherein the second metasurface lens functions as a beam expander.

8. The laser module according to claim 6, further comprising a cover layer covering the first metasurface lens.

9. The laser module according to claim 1,
wherein the first surface is an inner surface covering the emission port, and
wherein the second surface is an outer surface opposite to the inner surface.

10. The laser module according to claim 1, further comprising a mask configured to remove a part of light emitted from the first metasurface lens.
